(19) United States
(12) Patent Application Publication
(10) Pub. No.: US 2025/0100925 A1
(43) Pub. Date: Mar. 27, 2025

(54) SINTERED BODY

(71) Applicants: NGK ELECTRONICS DEVICES, INC., Mine-shi (JP); NGK INSULATORS, LTD., Nagoya-shi (JP)

(72) Inventors: Hiroshi KOUNO, Mine-shi (JP); Atsushi MASE, Mine-shi (JP)

(21) Appl. No.: 18/976,838

(22) Filed: Dec. 11, 2024

Related U.S. Application Data
(63) Continuation of application No. PCT/JP2023/021414, filed on Jun. 8, 2023.

(30) Foreign Application Priority Data
Jun. 13, 2022 (WO) PCT/JP2022/023646

(51) Int. Cl. C03C 10/00

(52) U.S. Cl. CPC C03C 10/0036

(57) ABSTRACT

Provided is a sintered body containing Al₂O₃, SiO₂, and MnO, the sintered body including: a main crystal phase formed of Al₂O₃; a first glass phase; and a second glass phase having a composition different from a composition of the first glass phase. The first glass phase and the second glass phase are phases each containing SiO₂ and MnO. A content ratio of SiO₂ to a sum of SiO₂ and MnO in the first glass phase is larger than a content ratio of SiO₂ to a sum of SiO₂ and MnO in the second glass phase.

This application is a continuation application of PCT/JP2023/021414, filed on Jun. 8, 2023, which claims the benefit of priority of International Patent Application No. PCT/JP2022/023646, filed on Jun. 13, 2022, the entire contents of which are incorporated herein by reference.

### TECHNICAL FIELD

The present disclosure relates to a sintered body containing alumina.

### BACKGROUND ART

As a material for a ceramic package or a circuit board, there has been known a sintered body that contains alumina (Al₂O₃) as a main component and a sintering aid. As the sintering aid, there have been known silica (SiO₂), manganese oxide (MnO), oxides of 2 a group elements, and the like.

As the sintered body described above, there has been known a sintered body containing alumina as a main crystal phase, Mn and Si at a percentage of from 12% by mass to 25% by mass in terms of oxide, and a 2 a group element in the periodic table at a percentage of from 2% by mass or less in terms of oxide, in which a ratio Mn₂O₃/SiO₂ of the Mn and the Si in terms of oxide is from 0.5 to 2 (see Japanese Patent Application Laid-open No. 2003-104772 (Patent Literature 1)). The sintered body is obtained by mixing an alumina raw material powder as a first component, a Mn₂O₃ powder and a SiO₂ powder at a specific ratio as a second component, and a powder of an oxide of a 2 a group element in the periodic table as a third component and baking the mixture. It is described that the obtained sintered body has characteristics including a relative density of 95% or higher, a strength of 400 MPa or higher, a Young's modulus of 300 GPa or lower, and a thermal conductivity of 10 W/mK or higher.

### CITATION LIST

### Patent Literature

[PTL 1] JP 2003-104772 A

### SUMMARY OF INVENTION

### Technical Problem

It is desired that the sintered body to be used as a material for a ceramic package or a circuit board have a high strength and a low Young's modulus. In Patent Literature 1, for example, the sintered body having the strength of 400 MPa or higher and the Young's modulus of 300 GPa or lower is obtained. However, it is desired that physical properties of the sintered body be further improved.

In view of the circumstances described above, one object of the present disclosure is to provide a sintered body having both of high strength and a low Young's modulus at a high level.

### Solution to Problem

A sintered body according to the present disclosure contains Al₂O₃, SiO₂, and MnO, and includes: a main crystal phase formed of Al₂O₃; a first glass phase; and a second glass phase having a composition different from a composition of the first glass phase. The first glass phase is a phase containing SiO₂ and MnO. The second glass phase is a phase containing SiO₂ and MnO. A content ratio of SiO₂ to a sum of SiO₂ and MnO in the first glass phase is larger than a content ratio of SiO₂ to a sum of SiO₂ and MnO in the second glass phase.

### Advantageous Effects of Invention

According to the sintered body described above, the sintered body having both of high strength and a low Young's modulus at a high level can be provided.

### BRIEF DESCRIPTION OF DRAWINGS

FIG. 1 is a schematic sectional view for illustrating a structure of a ceramic package.

FIG. 2 is one example of a SEM image of a sintered body according to the present disclosure.

FIG. 3 includes images obtained by binarizing the SEM image of the sintered body according to the present disclosure.

FIG. 4 includes SEM images of a sintered body of Comparative Example 2 and images for showing positions at which elemental analysis has been conducted.

FIG. 5 includes SEM images of a sintered body of Comparative Example 4 and images for showing positions at which the elemental analysis has been conducted.

FIG. 6 includes SEM images of a sintered body of Example 2 and images for showing positions at which the elemental analysis has been conducted.

FIG. 7 includes SEM images of a sintered body of Example 4 and images for showing positions at which the elemental analysis has been conducted.

FIG. 8 includes SEM images of a sintered body of Example 6 and images for showing positions at which the elemental analysis has been conducted.

FIG. 9 includes SEM images of a sintered body of Example 8 and images for showing positions at which the elemental analysis has been conducted.

FIG. 10 is a graph for showing a distribution of a Young's modulus and flexural strength of sintered bodies of Examples 1 to 8 and Comparative Examples 1 to 5.

FIG. 11 is a graph for showing a content ratio of SiO₂ to a sum of SiO₂ and MnO at positions at which the elemental analysis has been conducted for each of the sintered bodies of Comparative Examples 2 and 4 and Examples 2, 4, 6, and 8.

### DESCRIPTION OF EMBODIMENTS

### Overview of Embodiments

First, embodiments of the present disclosure are described in order. A sintered body according to a first aspect of the present disclosure contains Al₂O₃, SiO₂, and MnO, and includes: a main crystal phase formed of Al₂O₃; a first glass phase; and a second glass phase having a composition different from composition of the first glass phase. The first glass phase is a phase containing SiO₂ and MnO. The second glass phase is a phase containing SiO₂ and MnO. A content ratio of SiO₂ to a sum of SiO₂ and MnO in the first glass phase is larger than a content ratio of SiO₂ to a sum of SiO₂ and MnO in the second glass phase. In this application, the glass phase may contain, in addition to glass components being SiO₂ and MnO, a slight amount of a crystalline component of a ceramic component contained in the sintered body.

Electronic devices such as a smartphone and a wearable device have been increasingly downsized. Along with the downsizing of the electronic devices, components to be mounted in the devices, such as a ceramic package, are also required to be downsized. Meanwhile, when a thickness and a height of the component are reduced so as to promote downsizing, there arises a problem in that its physical strength may be reduced. For example, when the ceramic package and a lid are bonded to each other for hermetical sealing, thermal stress generated due to a difference in coefficient of thermal expansion between the package and the lid may damage the package. Thus, an increase in strength of ceramic has been under consideration. Meanwhile, it has been known that a lower Young's modulus of the ceramic is more preferred in terms of reduction of the stress.

The inventors of the present disclosure have conducted studies on the sintered body including the main crystal phase formed of alumina and the glass phases. As a result of the studies, the inventors of the present disclosure have found that two kinds of glass phases may be formed in the sintered body containing SiO₂ and MnO in addition to alumina. Moreover, the inventors of the present disclosure have found that the sintered body including the two kinds of glass phases have both of high strength and a low Young's modulus at a level higher than that in the related art. Further, the inventors of the present disclosure have found that the two kinds of glass phases have different content ratios of SiO₂ to the sum of SiO₂ and MnO and that the content ratio of SiO₂ in the first glass phase is larger than the content ratio of SiO₂ in the second glass phase. More specifically, the inventors of the present disclosure have found that the first glass phase is a phase containing SiO₂ at the content ratio of 65% by mass or more and less than 100% by mass to the sum of the SiO₂ and MnO (hereinafter also referred to as “Si-rich phase”) and the second glass phase is a phase containing SiO₂ at the content ratio of 35% by mass or more and less than 65% by mass (hereinafter also referred to as “Mn-rich phase”).

Without willing to be bound by any particular theory, it is considered that three kinds of phases with different toughness included in the sintered body according to the present disclosure may be one of factors in achievement of both of high strength and a low Young's modulus. It is considered that, in the sintered body according to the present disclosure, the main crystal phase formed of alumina has toughness relatively lower than toughness of the glass phases and the first glass phase having a large content ratio of SiO₂ has toughness higher than toughness of the second glass phase. When stress is applied to the sintered body, micro cracks are first formed in the phase of alumina having the lowest toughness. When the cracks develop and expand to most part of the sintered body, the sintered body breaks. Meanwhile, when the expanding cracks reach the glass phase having toughness higher than the toughness of alumina, the development of cracks may be deterred. Here, it is considered that the presence of two kinds of phases with different toughness as the glass phases improves an effect to stop the development of cracks, which enables achievement of both of high strength and a low Young's modulus.

The fact that the sintered body includes the main crystal phase formed of alumina, the first glass phase, and the second glass phase can be confirmed by, for example, checking three kinds of phases on a SEM image of a cross section of the sintered body and conducting elemental analysis for each of the phases. A specific specifying method is described later.

In the sintered body according to the present disclosure, a content ratio of a sum of SiO₂ and MnO to entire mass of the sintered body may be 11.0% by mass or more and 30.0% by mass or less. A content ratio of SiO₂ to the sum of SiO₂ and MnO may be 54.0% by mass or more and 66.6% by mass or less. When the content ratio of the glass phases in the sintered body falls within the above-mentioned range, both of high strength and a low Young's modulus can be achieved, and the sintered body can be stably and efficiently manufactured.

An area ratio of the first glass phase, which is obtained from an image obtained by binarizing a scanning electron microscopic image of the alumina sintered body, may be 0.1% by area or more and 10% by area or less to the sintered body. An area ratio of the second glass phase, which is obtained from an image obtained by binarizing a scanning electron microscopic image of the alumina sintered body, may be 10% by area or more and 30% by area or less to the sintered body.

A content ratio of each of the phases included in the sintered body is calculated from an area of each of the phases in an image that is obtained by observing a cross section of the sintered body with a scanning electron microscope (SEM), specifying the main crystal phase, the first glass phase, and the second glass phase as three kinds of phases with different densities on a SEM image, and then binarizing the SEM image.

In the sintered body according to the present disclosure, in addition to the second glass phase containing SiO₂ at the content ratio of 35% by mass or more and less than 65% by mass, the first glass phase containing SiO₂ at a higher content ratio is formed. When the first glass phase is formed at 0.1% by area or more, an effect of the presence of the first glass phase is obtained. Thus, the sintered body having both of a high strength and a low Young's modulus is obtained.

### Specific Examples of Embodiments

Next, specific embodiments of a sintered body according to the present disclosure are described.

### (Sintered Body)

The sintered body according to the present disclosure is a solid material obtained by sintering a ceramic material such as an alumina powder. The sintered body is typically obtained by sintering a green sheet obtained by shaping a ceramic material powder into a tape-like shape or a green body obtained by compacting a ceramic material powder.

### (Structure of Sintered Body)

The sintered body according to the present disclosure includes the crystal phase and two kinds of glass phases. In the sintered body according to the present disclosure, the alumina phase, the first glass phase, and the second glass phase are randomly present without specific regularity. The alumina phase, the first glass phase, and the second glass phase are phases each characterized by compositions, and are specified as, for example, three kinds of portions having different densities on an image (SEM image) obtained by observing a cross section of the sintered body with a scanning electron microscope.

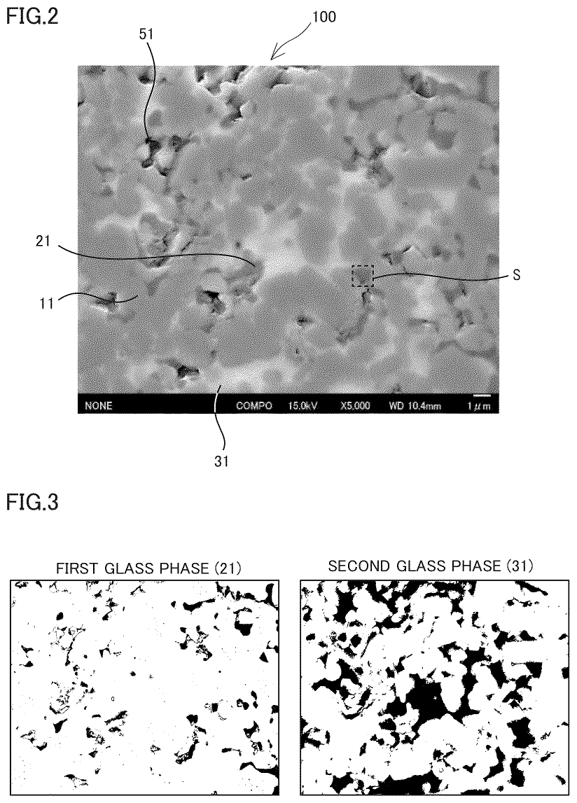

FIG. 2 is one example of a SEM image of the sintered body according to the present disclosure. As shown in FIG. 2, on the SEM image, an alumina phase 11 of a sintered body 100 is observed as an opaque grey portion. On the SEM image, the alumina phase 11 is observed mainly as a continuous form of a large number of particles joined at their interfaces. A part of the alumina phase 11 is observed as an independent particle form. The morphology of the alumina phase in the sintered body is not limited to that of the example shown in FIG. 2. A degree of joint between particles may be larger, or the alumina phase may have a larger number of independent particles.

On the SEM image, a first glass phase 21 of the sintered body 100 is darker than the alumina phase 11. On the SEM image, the first glass phase 21 is observed typically as an irregularly shaped particle form. A shape of the first glass phase 21 is not limited to a particle shape and may be an irregular continuous shape. Sizes of the particles of the first glass phase 21 are not limited to any particular sizes. As one example, when a minimum rectangle S surrounding a particle is supposed, a percentage of the particles, each being surrounded by the rectangle S with sides each having a length smaller than 5 μm, in the first glass phase 21 is 50% or more, preferably 80% or more.

On the SEM image, a second glass phase 31 of the sintered body 100 is brighter than the alumina phase 11. On the SEM image, the second glass phase 31 typically has a form resulting from solidification after flowing and expanding so as to fill gaps in the alumina phase 11. The second glass phase 31 is observed as an irregular portion extending so as to surround the alumina phase 11 and the first glass phase 21. In the sintered body according to the present disclosure, two kinds of glass phases are present so as to fill the gaps in the alumina phase 11 that is present in a particle shape or a shape of joined particles. The second glass phase 31 is present as an irregular net-like portion in the sintered body.

On the SEM image, portions observed as black portions are air gaps 51.

A content ratio of the first glass phase and a content ratio of the second glass phase in the sintered body are expressed as values (% by area) obtained by monochromatically binarizing the SEM image of the sintered body with image processing software and calculating an area ratio of the first glass phase 21 and an area ratio of the second glass phase 31 to the entire area of the image. A specific calculation method is, for example, as follows. Specifically, a SEM image of the sintered body, which is to be subjected to calculation, is prepared. For the image, a histogram having a horizontal axis representing a brightness value (for example, from 0 to 255) and a vertical axis representing an appearance frequency is created. Subsequently, threshold values of brightness values for defining the air gaps and the phases. i.e., the first glass phase, the alumina phase, and the second glass phase are determined with reference to the image. After the threshold values are determined, an integrated value of the appearance frequency in each of the sections is calculated, and a ratio of the integrated value of each of the sections to an integrated value of the appearance frequency at all the brightness values is determined. As the image processing software, for example, publicly known software such as “ImageJ” can be used. FIG. 3 includes images obtained by binarizing the SEM image of FIG. 2 by the method described above and then extracting the first glass phase 21 and the second glass phase 31. The left image of FIG. 3 is a binarized image of the first glass phase (a black region represents the first glass phase, and a white region represents the other phases), and the right image is a binarized image of the second glass phase (a black region represents the second glass phase, and a white region represents the other phases).

It is preferred that the sintered body according to the present disclosure include the first glass phase at the content ratio of 0.1% by area or more and 10% by area or less based on the calculation of the content ratio by the above-mentioned binarization analysis. It is considered that, when the first glass phase is contained at 0.1% by area or more, an effect of the present disclosure, i.e., achievement of both of high strength and a low Young's modulus is obtained. Further, when the first glass phase is contained at the content ratio of 10% by area or less, the sintered body having excellent stability at the time of manufacture with high production efficiency is obtained.

It is preferred that the sintered body according to the present disclosure include the second glass phase at the content ratio of 10% by area or more and 30% by area or less based on the calculation of the content ratio by the above-mentioned binarization analysis. When the content ratio of the second glass phase is 10% by area or more, an effect to form dense ceramic having an excellent sintering property is obtained. When the content ratio of the second glass phase is 30% by area or less, the sintered body having excellent stability at the time of manufacture with high production efficiency is obtained.

A relative ratio between the first glass phase and the second glass phase is not limited to any particular ratio. For example, the content ratio of the first glass phase to a sum of the content ratios of the first glass phase and the second glass phase may be 0.3% by area or more and 50% by area or less. In a related-art sintered body, only the second glass phase is formed. Meanwhile, the sintered body according to the present disclosure includes, in addition to the second glass phase, the first glass phase containing Si at a high content ratio. It is considered that, when the glass phases include the first glass phase at 0.3% by area or more, an effect of the presence of the first glass phase is obtained.

### (Composition of Sintered Body)

As described above, the sintered body according to the present disclosure includes at least three kinds of phases. Now, compositions of the crystal phase and the glass phases of the sintered body according to the present disclosure are described.

In the sintered body according to the present disclosure, the crystal phase includes a main crystal phase formed of Al₂O₃ (hereinafter also referred to as “alumina phase”). The crystal phase may include only the alumina phase or may also include another crystal phase. For example, when the sintered body contains Mo as a colorant, a Mo crystal phase may be included in addition to the alumina phase. Further, one, two, or more kinds of other crystal phases may be included. When the crystal phase includes the alumina phase and other phases, a content ratio of the alumina phase to the entire crystal phase is not limited to any particular ratio. It is preferred that the content ratio be, for example, 50% by volume or more.

The sintered body according to the present disclosure includes at least two kinds of glass phases having different compositions as the glass phases. Here, the wording “different compositions” refers to at least any of a kind or a content ratio of a composition for forming the glass phase being different. The glass phases contain SiO₂ and MnO as essential components. Next, each of two kinds of glass phases is described.

The first glass phase is a phase containing SiO₂ and MnO, in which a content ratio of SiO₂ to a sum of SiO₂ and MnO is 65% by mass or more and less than 100% by mass. It is preferred that the first glass phase contain SiO₂ at the content ratio of from 75% by mass to 99% by mass to the sum of SiO₂ and MnO. The content ratio of SiO₂ and the content ratio of MnO are obtained by calculating a content ratio of Si atoms and a content ratio of Mn atoms at observation locations from measurement values obtained through elemental analysis of the glass phase and then converting the content ratios into mass of SiO₂ and mass of MnO. The first glass phase contains SiO₂ at a remarkably large content ratio in comparison to the second glass phase. For example, the content ratio of SiO₂ in the first glass phase may be 1.2 times or more larger, more preferably 1.5 times or more larger than the content ratio of SiO₂ in the second glass phase.

The elemental analysis of the glass phase can be conducted using a publicly known analysis method such as a scanning electron microscope-energy dispersive X-ray spectrometry (SEM-EDX), X-ray fluorescent spectrometry (XRF), or inductively coupled plasma atomic emission spectroscopy (ICP-AES).

The second glass phase is a phase containing SiO₂ and MnO, in which a content ratio of SiO₂ to a sum of SiO₂ and MnO is 35% by mass or more and less than 65% by mass. It is preferred that the second glass phase contain SiO₂ at the content ratio of from 40% by mass to 60% by mass to the sum of SiO₂ and MnO.

The first glass phase and the second glass phase may be formed only of SiO₂ and MnO, and may also contain a component other than SiO₂ and MnO. The component other than SiO₂ and MnO is not limited to any particular one as long as the effect of the present disclosure is obtained.

The content ratios of the components of the sintered body having the above-mentioned structure can be set to fall within, for example, the following ranges.
Al₂O₃: 70.0% by mass or more and 89.0% by mass or less to the entire mass of the sintered body.
SiO₂: 5.7% by mass or more and 20.0% by mass or less to the entire mass of the sintered body.
MnO: 3.7% by mass or more and 11.0% by mass or less to the entire mass of the sintered body.

In the sintered body according to the present disclosure, the content ratios the sum of SiO₂ and MnO (the sum of mass) to the entire mass of the sintered body may be 11.0% by mass or more and 30.0% by mass or less, more preferably 11.8% by mass or more and 24.4% by mass or less. When the sum is smaller than 11.0% by mass, two kinds of glass phases are not formed. When the sum is larger than 30% by mass, adhesion to a setter at the time of baking or the like is liable to occur. Thus, it is difficult to obtain a sintered body with high production efficiency.

In the sintered body according to the present disclosure, the ratio of SiO₂ to the sum of SiO₂ and MnO may be 54.0% by mass or more and 66.6% by mass or less, more preferably 56.0% by mass or more and 62.9% by mass or less. It has been found that, when the ratio is less than 54.0% by mass, two kinds of glass phases are not generated in the sintered body and, when the ratio is more than 66.6% by mass, it is difficult to form a dense sintered body.

The sintered body according to the present disclosure may be formed only of the components described above and inevitable impurities. The inevitable components may be, for example, 0.1 wt % or less in terms of oxide.

### (Physical Properties of Sintered Body)

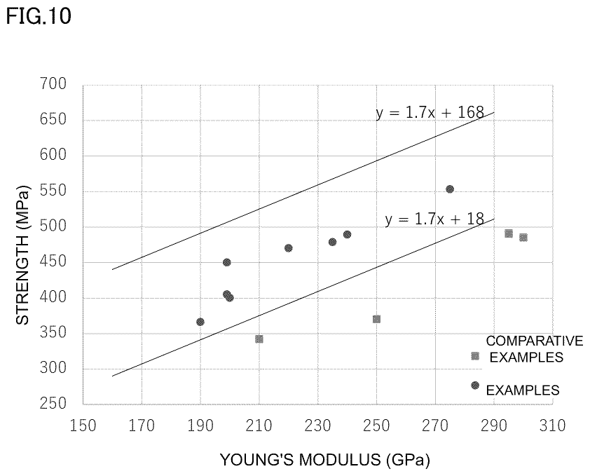

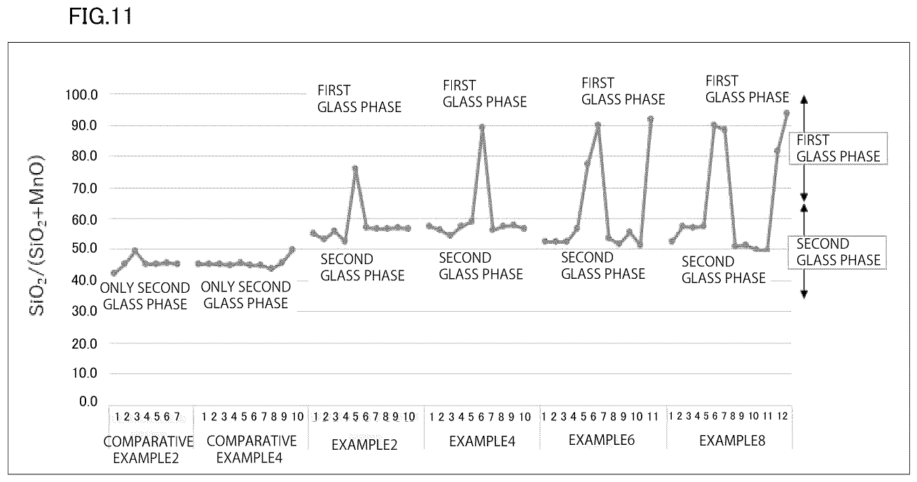

The strength of the sintered body according to the present disclosure can be set in accordance with a purpose of use, and may be 300 MPa or higher, more preferably 400 MPa or higher. The term “strength” as used herein refers to so-called “flexural strength”, and is an average value of values obtained by measurement performed at a room temperature in compliance with a three-point bending test method based on JIS R1601 (bending test method for fine ceramics). Higher strength is more preferred. However, as the strength becomes higher, the Young's modulus also becomes higher. On a graph (FIG. 10) having a vertical axis, i.e., a y-axis representing strength (unit: MPa) and a horizontal axis, i.e., an x-axis representing the Young's modulus (unit: GPa), coordinates of the strength and the Young's modulus of the sintered body may lie between a straight line: y=1.7x+18 and a straight line: y=1.7x+168. Thus, the strength may be 660 MPa or lower, more preferably 600 MPa or lower.

The Young's modulus of the sintered body according to the present disclosure can be set in accordance with a purpose of use, and may be 290 GPa or lower, more preferably 280 GPa or lower. The Young's modulus is an average value of values obtained by measurement performed at a room temperature in compliance with a measurement method using a strain gauge for three-point bending based on JIS R1602. Lower Young's modulus is more preferred. However, as the Young's modulus becomes lower, the strength also becomes lower. On a graph having a vertical axis, i.e., a y-axis representing strength (unit: MPa) and a horizontal axis, i.e., an x-axis representing the Young's modulus (unit: GPa), coordinates of the strength and the Young's modulus of the sintered body may lie between a straight line: y=1.7x+18 and a straight line: y=1.7x+168. Thus, the Young's modulus may be 170 GPa or higher, more preferably 190 GPa or higher.

A porosity of the sintered body is not limited to any particular porosity. When the sintered body is applied to, for example, a ceramic package for sealing an oscillator or a semiconductor element, it is preferred that the porosity be 3% by area or less. Further, when the sintered body is applied to a ceramic package for sealing an optical semiconductor element, it is preferred that the porosity be 3% by area or more and 8% by area or less. The porosity is a value obtained by photographing a cross section of the sintered body with a scanning electron microscope, binarizing the image with image processing software, and then measuring an area ratio of air gaps.

### (Method of Manufacturing Sintered Body)

When the sintered body according to the present disclosure is used to form a ceramic package, the sintered body can be manufactured by, for example, the following method. First, a green-sheet preparation step is carried out. Specifically, an Al₂O₃ powder being a main component of the sintered body, a SiO₂ powder being a sintering aid, a Mn compound powder, a resin, a solvent, and the like are mixed in a ball mill to obtain slurry. It is preferred that a Mn salt, specifically, MnCO₃ be used as the Mn compound. The slurry is processed into a green sheet by a doctor blade method. A shape of the green sheet can be determined in accordance with a shape of a component to be formed. When, for example, a bottom wall portion of the package or a circuit board is to be formed, a green sheet having a rectangular shape in plan view is prepared. When a frame portion of the package is to be formed, an annular green sheet obtained by removing a portion corresponding to a cavity is prepared.

Next, an electroconductive-portion printing step is carried out. In this step, a paste used to form the electroconductive portions is printed on the green sheets, which have been prepared in the previous step. Specifically, the metal powder, which is at least one of W, Mo, or Cu, an additive, a resin, a solvent, and the like are blended. Further, a ceramic powder is added as needed and kneaded to form a paste.

The paste is printed by, for example, screen printing on the green sheets prepared in the previous step. When, for example, the green sheet is used to form the bottom wall portion of the ceramic package, the paste for the electroconductive portion is printed on a region corresponding to an external terminal. Similarly, the paste for the electroconductive portion is printed at a position corresponding to a final shape. After the paste for the electroconductive portion is printed, the green sheet is dried. The drying can be performed under a condition of, for example, heating at 110° C. and holding for five minutes. After the drying, the green sheets are laminated to obtain a green sheet laminate.

Next, a baking step is carried out. In this step, the laminate of the green sheets, which has been prepared in the previous step, is baked. The baking is performed by, for example, heating at a temperature of 1,150° C. or higher and 1,300° C. or lower in an atmosphere of a mixture of hydrogen, nitrogen, and water vapor. It is more preferred that a baking temperature be 1,200° C. or higher and 1,250° C. or lower. It is considered that, when the baking is performed at a temperature falling within the above-mentioned temperature range, two glass phases having different compositions are highly likely to be formed.

### (Purpose of Use of Sintered Body)

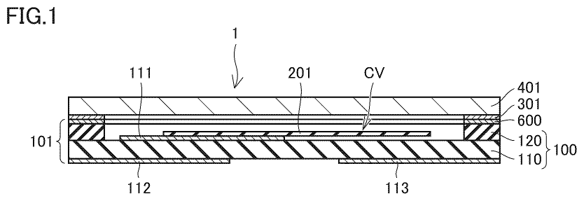

A purpose of use of the sintered body according to the present disclosure is not limited to any particular purpose of use. As one of specific purposes of use, the sintered body is used as a member for forming a package that houses a chip of a crystal unit or the like. FIG. 1 is a sectional view for schematically illustrating a structure of a crystal unit using the sintered body according to the present disclosure. A crystal unit 1 includes a package 101, a crystal blank 201, a brazing filler metal 301, and a lid 401. The package 101 has a cavity CV. The crystal blank 201 is received in the cavity CV. The crystal blank 201 is mounted on an element electrode pad 111 of the package 101. Package electrode pads 112 and 113 are arranged on a base portion 100 outside the cavity CV.

The base portion 100 of the package 101 is made of the sintered body (ceramic) according to the present disclosure. The base portion 100 includes a board portion 110 and a frame portion 120. The board portion 110 forms a bottom surface of the cavity CV. The frame portion 120 is laminated on the board portion 110 in a thickness direction (vertical direction in FIG. 1).

The lid 401 is bonded to a metallization layer 600 of the package 101 with the brazing filler metal 301. The lid 401 and the package 101 are bonded to each other through intermediation of the brazing filler metal 301 to thereby seal the cavity CV. It is preferred that the brazing filler metal 301 be typically made of an alloy containing gold, and the brazing filler metal 301 may be, for example, an alloy containing gold and tin (Au—Sn-based alloy). The lid 401 is made of metal, for example, an alloy containing iron and nickel.

The metallization layer 600 is made of, for example, metal containing at least any of molybdenum (Mo) or tungsten (W). A plating layer may be formed on a surface of the metallization layer 600 (surface facing the brazing filler metal 301). Typically, a gold plating layer is formed. A nickel plating layer may be formed as an underlayer for the gold plating layer.

The sintered body according to the present disclosure is suitably used as a material for forming, for example, various kinds of ceramic packages such as a ceramic package for sealing a semiconductor element such as a CMOS image sensor and a ceramic package for sealing an optical semiconductor element, and a circuit board. The sintered body according to the present disclosure may have various shapes in accordance with the purpose of use. When the sintered body is used for a package, its shape is as described above. Besides, the sintered body according to the present disclosure may have various shapes such as a plate-like shape, a cuboidal shape, and a membranous shape.

### Examples

Sintered bodies of Examples 1 to 8 and Comparative Examples 1 to 5 were produced, and their morphologies were observed. Further, strength and a Young's modulus of each of the sintered bodies were measured.

### (Production of Samples)

An alumina powder having an average particle diameter of 1.8 μm, a MnCO₃ powder having an average particle diameter of 3.5 μm, and a SiO₂ powder having an average particle diameter of 1.2 μm were mixed at ratios shown in Table 1 to obtain a mixed powder. In Table 1, feed amounts (mixture ratio) of the powders and calculation values (values of MnCO₃ in terms of MnO) obtained from the feed amounts are shown.

In Example 7, a MoO₃ powder was added as an additive. When the sum of the above-mentioned three kinds of powders was defined as 100% by mass, the amount of addition of the MoO₃ powder was 0.5% by mass. Further, in Table 1, a value of MnCO₃ in terms of MnO, a sum of SiO₂ and MnO, and a content ratio of SiO₂ to the sum of SiO₂ and MnO are shown. The content ratio of SiO₂ to the sum of SiO₂ and MnO is expressed by: SiO₂/(SiO₂+MnO).

Polyvinyl butyral, tertiary amine, and phthalic ester (diisononyl phthalate: DINP) were mixed as organic components with the obtained mixed powder. Further, isopropyl alcohol (IPA) and toluene were mixed as solvents to prepare slurry.

A ceramic tape having a thickness of from 50 μm to 400 μm was produced with the prepared slurry by the doctor blade method. The obtained ceramic tape was cut into pieces, each having a length of 50 mm and a width of 50 mm. The pieces were placed on a baking setter made of Mo and were maintained at a baking temperature (maximum temperature) shown in Table 1 for two hours in an atmosphere of a mixture of hydrogen, nitrogen, and water vapor at a dew point of 35° C. so as to be baked. One hundred sintered bodies were formed for each of Examples 1 to 8 and Comparative Examples 1 to 5. A temperature variation in a furnace at the time of baking performed at a baking temperature shown in Table 1 fell within a range of ±5° C. Further, proportions of the feed amounts of Al, Si, Mn, and Mo were the same as proportions after the baking within an error range.

TABLE 1

| | | | | | | | | | | | Baking |
|---|---|---|---|---|---|---|---|---|---|---|---|
| | Feed amounts | | | | Calculated values from feed amounts | | | | | | temperature |
| | (% by mass) | | | | (% by mass) | | | | | | (° C.) |
| | | | | Other | | | | Other | | SiO₂/ | keeping |
| | | | | additive | | | | additive | SiO₂ + | (SiO₂ + | time |
| | Al₂O₃ | SiO₂ | MnCO₃ | * | Al₂O₃ | SiO₂ | MnO | ** | MnO | MnO) | 2 hr |
| Comparative | 82.1 | 4.8 | 13.1 | None | 86.5 | 5.0 | 8.5 | None | 13.5 | 37.0 | 1,200 |
| Example 1 | | | | | | | | | | | |
| Comparative | 65.5 | 9.2 | 25.3 | None | 72.5 | 10.2 | 17.3 | None | 27.5 | 37.1 | 1,200 |
| Example 2 | | | | | | | | | | | |
| Comparative | 84.0 | 5.7 | 10.3 | None | 87.5 | 5.9 | 6.6 | None | 12.5 | 47.2 | 1,200 |
| Example 3 | | | | | | | | | | | |
| Comparative | 68.3 | 11.2 | 20.5 | None | 74.1 | 12.2 | 13.7 | None | 25.9 | 47.1 | 1,200 |
| Example 4 | | | | | | | | | | | |
| Comparative | 87.4 | 5.4 | 7.2 | None | 89.8 | 5.7 | 4.5 | None | 10.2 | 55.9 | 1,200 |
| Example 5 | | | | | | | | | | | |
| Example 1 | 85.5 | 6.4 | 8.1 | None | 88.2 | 6.6 | 5.2 | None | 11.8 | 55.9 | 1,200 |
| Example 2 | 78.2 | 9.6 | 12.2 | None | 82.0 | 10.1 | 7.9 | None | 18.0 | 56.1 | 1,225 |
| Example 3 | 78.2 | 9.6 | 12.2 | None | 82.0 | 10.1 | 7.9 | None | 18.0 | 56.1 | 1,250 |
| Example 4 | 71.0 | 12.9 | 16.1 | None | 75.6 | 13.8 | 10.6 | None | 24.4 | 56.6 | 1,200 |
| Example 5 | 77.3 | 11.6 | 11.1 | None | 80.7 | 12.1 | 7.2 | None | 19.3 | 62.7 | 1,200 |
| Example 6 | 72.6 | 14.0 | 13.4 | None | 76.5 | 14.8 | 8.7 | None | 23.5 | 63.0 | 1,200 |
| Example 7 | 72.6 | 14.0 | 13.4 | MoO₃ | 76.5 | 14.8 | 8.7 | MoO₃ | 23.5 | 63.0 | 1,200 |
| | | | | 0.5% | | | | 0.5% | | | |
| Example 8 | 73.1 | 14.5 | 12.4 | None | 76.8 | 15.2 | 8.0 | None | 23.2 | 65.5 | 1,200 |

* Amount when Al₂O₃ + SiO₂ + MnCO₃ is defined as 100
** Amount when Al₂O₃ + SiO₂ + MnO is defined as 100

### (Morphology Observation)

The sintered bodies of Examples 1 to 8 and Comparative Examples 1 to 5 were polished with a cross-section polisher (CP) (manufactured by JEOL Ltd., IB-15000CP). Obtained cross sections were observed with a field emission scanning electron microscope (SEM) (manufactured by JEOL Ltd., JSM-7000F) to obtain SEM images. A gold film was formed on a cross section of the sintered body by sputtering, and the cross section was observed in a reflection electron mode. An acceleration voltage was set to 15.0 kV, and a magnification was set to ×5,000. The phases included in each of the sintered bodies were checked on the image. Further, a histogram having a horizontal axis representing a brightness value (from 0 to 255) and a vertical axis representing an appearance frequency was created for the SEM image of each of the sintered bodies. Next, with reference to the SEM image, threshold values of brightness values, which define the air gaps and the phases, i.e., the first glass phase, the alumina phase, and the second glass phase, were determined. After the threshold values were determined, an integrated value of the frequencies in each of the sections of the first glass phase and the second glass phase was calculated. A ratio of the integrated value of the first glass phase and a ratio of the integrated value of the second glass phase to the integrated value of the appearance frequency at all the brightness values were defined as the content ratio (% by area) of the first glass phase and the content ratio of the second glass phase, respectively. As image processing software, “ImageJ” was used. The results are shown in Table 2.

### (Measurement of Strength and Young's Modulus)

For the sintered bodies of Examples 1 to 8 and Comparative Examples 1 to 5, flexural strength was measured at a room temperature in accordance with three-point bending test method based on JIS R1601. Further, a Young's modulus was measured in accordance with a measurement method using a strain gauge for three-point bending based on JIS R1602. The results are shown in Table 2 and FIG. 10.

TABLE 2

| | Results of binarization analysis on | | | |
|---|---|---|---|---|
| | cross section (% by area) | | | |
| | SiO₂ content in | SiO₂ content in | Properties | |
| | first glass | second glass | | Young's |
| | phase | phase | Strength | modulus |
| | 65% to 100% | 35% to 65% | (MPa) | (GPa) |
| Comparative | 0 | 15.1 | 490 | 295 |
| Example 1 | | | | |
| Comparative | 0 | 33.3 | 370 | 250 |
| Example 2 | | | | |
| Comparative | 0 | 14.9 | 491 | 295 |
| Example 3 | | | | |
| Comparative | 0 | 31.8 | 342 | 210 |
| Example 4 | | | | |
| Comparative | 0 | 12.3 | 485 | 300 |
| Example 5 | | | | |
| Example 1 | 0.1 | 14.8 | 553 | 275 |
| Example 2 | 0.4 | 18.6 | 489 | 240 |
| Example 3 | 0.4 | 18.6 | 478 | 235 |
| Example 4 | 1.5 | 26.1 | 470 | 220 |
| Example 5 | 6.3 | 22.7 | 450 | 199 |
| Example 6 | 7.5 | 23.0 | 400 | 200 |
| Example 7 | 7.5 | 23.0 | 405 | 199 |
| Example 8 | 5.2 | 25.8 | 366 | 190 |

As shown in Table 2, it was confirmed that the sintered bodies of Examples 1 to 8 included two kinds of glass phases, i.e., the first glass phase and the second glass phase. The content ratio of the first glass phase in the sintered bodies ranged from 0.1% by area to 7.5% by area. The content ratio of the second glass phase ranged from 14.8% by area to 26.1% by area. Meanwhile, the first glass phase was not observed in the sintered bodies of Comparative Examples 1 to 5. The content ratio of the second glass phase ranged from 12.3% by area to 33.3% by area. Further, the sintered bodies of Examples 1 to 8 had the strength of 366 MPa or higher and the Young's modulus of 275 GPa or lower.

FIG. 10 is a graph for showing a distribution of the Young's modulus and the flexural strength of the sintered bodies of Examples 1 to 8 and Comparative Examples 1 to 5. In FIG. 10, a horizontal axis represents the Young's modulus and a vertical axis represents the flexural strength. As shown in FIG. 10, the sintered bodies of Example 1 to 8 are distributed in the upper left (lower Young's modulus and higher flexural strength) of the graph in comparison to the sintered bodies of Comparative Examples 1 to 5. Specifically, when the Young's modulus is the same, the sintered bodies of Examples have higher flexural strength than the sintered bodies of Comparative Examples. Further, when the flexural strength is the same, the sintered bodies of Examples have lower Young's moduli than the sintered bodies of Comparative Examples. As shown in FIG. 10, coordinates of the flexural strength and the Young's modulus of all the sintered bodies of Examples 1 to 8 lie between the straight line: y=1.7x+18 and the straight line: y=1.7x+168 on the graph having the y-axis representing the flexural strength (MPa) and the x-axis representing the Young's modulus (GPa). Meanwhile, the coordinates of the flexural strength and the Young's modulus of all the sintered bodies of Comparative Examples 1 to 5 lie outside the range defined by the two straight lines. A ratio of a value of the flexural strength (MPa) to a value of the Young's modulus (GPa) is calculated. Then, the ratio ranges from 1.92 to 2.26 in Examples 1 to 8, whereas the ratio ranges from 1.48 to 1.66 in Comparative Examples 1 to 5. From the results described above, it was confirmed that the sintered bodies of Examples 1 to 8 had both of high strength and a low Young's modulus.

### (Elemental Analysis)

For the sintered bodies of Comparative Examples 2 and 4 and Examples 2, 4, 6, and 8, a plurality of positions at which the glass phases were observed were selected on the obtained SEM image. Then, point analysis was conducted with an EDS (manufactured by JEOL Ltd., JSM-7000F). The sintered bodies of Comparative Examples included one kind of glass phase, and a plurality of positions at which the glass phase was observed were selected. The sintered bodies of Examples had two kinds of glass phases, and each of the two kinds of glass phases was selected.

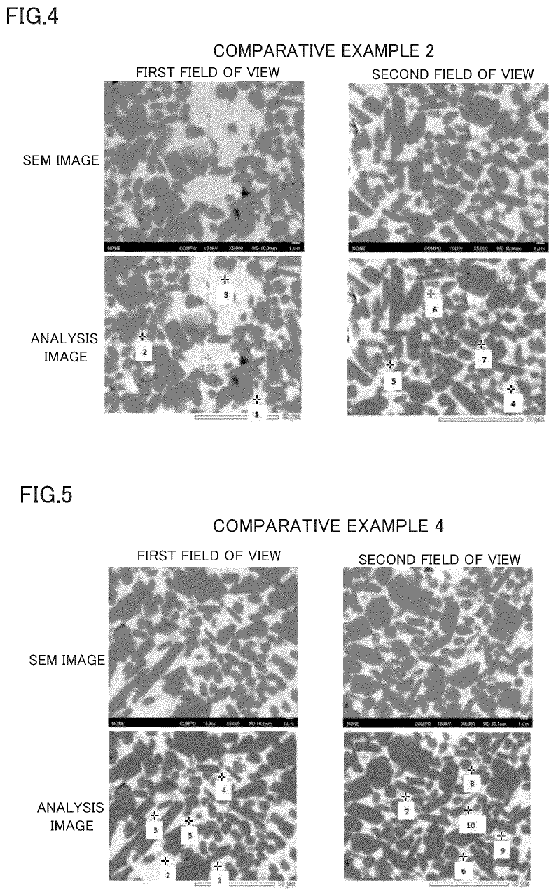

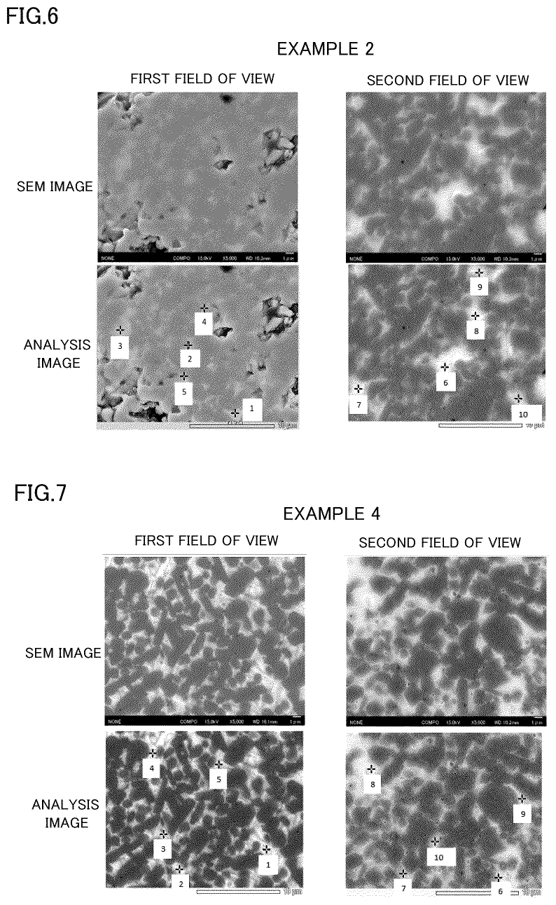

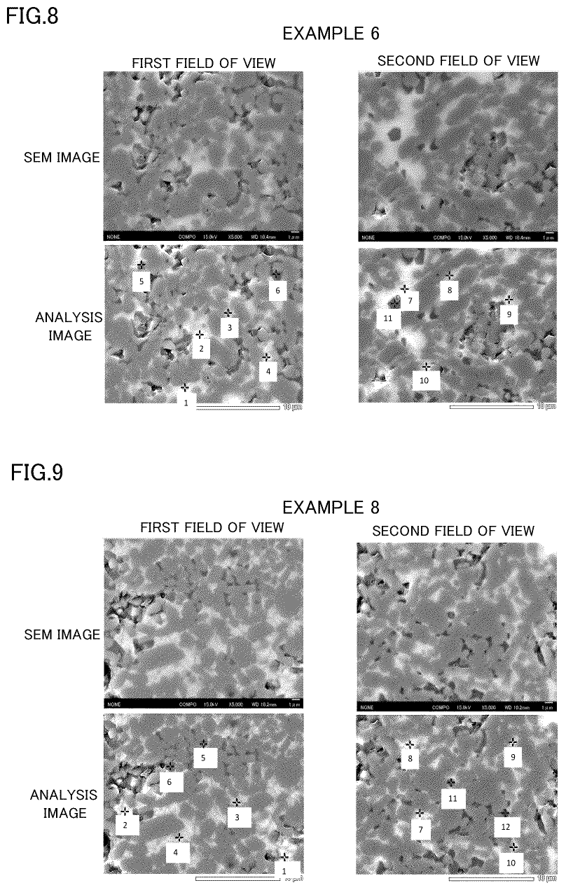

A SEM image and an analysis image (image with the positions on the SEM image, at which the elemental analysis was conducted) of Comparative Example 2 are shown in FIG. 4, those of Comparative Example 4 in FIG. 5, those of Example 2 in FIG. 6, those of Example 4 in FIG. 7, those of Example 6 in FIG. 8, and those of Example 8 in FIG. 9. The position at which the elemental analysis was conducted is indicated with a cross. Two fields of view were analyzed for each of the examples. In Tables 3 to 5, the content ratio (% by mass) of SiO₂ and the content ratio of MnO, which are calculated from the results of elemental analysis conducted at the positions shown in FIG. 4 to FIG. 9, are shown. Numerical values of SiO₂ and MnO in analysis values of Tables 3 to 5 are conversion values obtained by converting blending ratios of a Si element and a Mn element in terms of SiO₂ and MnO, and the sum of SiO₂ and MnO is not equal to 100%.

TABLE 3

| | | Comparative Example 2 | | | | | | |
|---|---|---|---|---|---|---|---|---|
| Position number | | 1 | 2 | 3 | 4 | 5 | 6 | 7 |
| Analysis | SiO₂ | 47.9 | 48.9 | 52.8 | 52.4 | 47.1 | 54.6 | 38.0 |
| values | MnO | 65.7 | 58.9 | 54.4 | 63.8 | 56.6 | 65.3 | 46.1 |
| | SiO₂/(SiO₂ + MnO) | 42.2 | 45.4 | 49.3 | 45.1 | 45.4 | 45.5 | 45.2 |

| | | | | | | | |
|---|---|---|---|---|---|---|---|
| Type of glass phase | 2 | 2 | 2 | 2 | 2 | 2 | 2 |

| | | Comparative Example 4 | | | | | | | | | |
|---|---|---|---|---|---|---|---|---|---|---|---|
| Position number | | 1 | 2 | 3 | 4 | 5 | 6 | 7 | 8 | 9 | 10 |
| Analysis | SiO₂ | 53.7 | 53.8 | 52.8 | 54.1 | 40.1 | 44.4 | 46.3 | 45.4 | 42.1 | 29.9 |
| values | MnO | 64.9 | 65.1 | 64.2 | 66.5 | 47.6 | 54.9 | 57.2 | 58.5 | 50.1 | 30.0 |
| | SiO₂/(SiO₂ + MnO) | 45.3 | 45.2 | 45.1 | 44.9 | 45.7 | 44.7 | 44.7 | 43.7 | 45.7 | 49.9 |

| | | | | | | | | | | |
|---|---|---|---|---|---|---|---|---|---|---|
| Type of glass phase | 2 | 2 | 2 | 2 | 2 | 2 | 2 | 2 | 2 | 2 |

As shown in FIG. 4, in Comparative Example 2, one kind of glass phase was observed on the SEM image. Further, as shown in Table 3, in Comparative Example 2, the content ratio of SiO₂ to the sum of SiO₂ and MnO at seven measurement positions for the glass phase ranged from 42.2% by mass to 49.3% by mass.

As shown in FIG. 5, in Comparative Example 4, one kind of glass phase was observed on the SEM image. Further, as shown in Table 3, in Comparative Example 4, the content ratio of SiO₂ to the sum of SiO₂ and MnO at ten measurement positions for the glass phase ranged from 43.7% by mass to 49.9% by mass.

TABLE 4

| | | Example 2 | | | | | | | | | |
|---|---|---|---|---|---|---|---|---|---|---|---|
| Position number | | 1 | 2 | 3 | 4 | 5 | 6 | 7 | 8 | 9 | 10 |
| Analysis | SiO₂ | 61.3 | 53.8 | 59.6 | 48.2 | 79.3 | 69.5 | 73.1 | 64.4 | 60.1 | 60.8 |
| values | MnO | 50.3 | 47.7 | 47.2 | 43.8 | 25.1 | 52.6 | 56.1 | 49.5 | 45.3 | 46.6 |
| | SiO₂/(SiO₂ + MnO) | 54.9 | 53.0 | 55.8 | 52.4 | 76.0 | 56.9 | 56.6 | 56.5 | 57.0 | 56.6 |
| | Type of glass | 2 | 2 | 2 | 2 | 1 | 2 | 2 | 2 | 2 | 2 |
| | phase | | | | | | | | | | |
| | | Example 4 | | | | | | | | | |
| Position number | | 1 | 2 | 3 | 4 | 5 | 6 | 7 | 8 | 9 | 10 |
| Analysis | SiO₂ | 72.8 | 64.2 | 57.6 | 65.9 | 52.7 | 77.7 | 59.2 | 71.1 | 63.1 | 56.7 |
| values | MnO | 54.3 | 50.4 | 48.3 | 48.8 | 36.6 | 9.6 | 46.3 | 52.7 | 46.2 | 43.8 |
| | SiO₂/(SiO₂ + MnO) | 57.3 | 56.0 | 54.4 | 57.5 | 59.0 | 89.0 | 56.1 | 57.4 | 57.7 | 56.4 |
| | Type of glass | 2 | 2 | 2 | 2 | 2 | 1 | 2 | 2 | 2 | 2 |
| | phase | | | | | | | | | | |

As shown in FIG. 6, in Example 2, two kinds of glass phases were observed on the SEM image. Further, as shown in Table 4, in Example 2, the content ratio of SiO₂ to the sum of SiO₂ and MnO at nine positions (measurement positions 1 to 4 and 6 to 10) at which the glass phase appeared bright among ten measurement positions for the glass phases ranged from 52.4% by mass to 57.0% by mass. The content ratio of SiO₂ to the sum of SiO₂ and MnO at one position (measurement position 5) at which the glass phases appeared dark was 76.0% by mass.

As shown in FIG. 7, in Example 4, two kinds of glass phases were observed on the SEM image. Further, as shown in Table 4, in Example 4, the content ratio of SiO₂ to the sum of SiO₂ and MnO at nine positions (measurement positions 1 to 5 and 7 to 10) at which the glass phase appeared bright among ten measurement positions for the glass phases ranged from 54.4% by mass to 59.0% by mass. The content ratio of SiO₂ to the sum of SiO₂ and MnO at one position (measurement position 6) at which the glass phases appeared dark was 89.0 by mass.

TABLE 5

| | | Example 6 | | | | | | | | | | |
|---|---|---|---|---|---|---|---|---|---|---|---|---|
| Position number | | 1 | 2 | 3 | 4 | 5 | 6 | 7 | 8 | 9 | 10 | 11 |
| Analysis | SiO₂ | 58.5 | 51.6 | 43.4 | 64.3 | 96.2 | 99.5 | 69.8 | 47.5 | 40.6 | 50.7 | 152.0 |
| values | MnO | 53.4 | 47.0 | 39.4 | 49.4 | 28.0 | 11.0 | 60.5 | 44.5 | 32.4 | 48.0 | 13.9 |
| | SiO₂/(SiO₂ + | 52.3 | 52.3 | 52.4 | 56.6 | 77.5 | 90.0 | 53.6 | 51.6 | 55.6 | 51.4 | 91.6 |
| | MnO) | | | | | | | | | | | |
| | Type of | 2 | 2 | 2 | 2 | 1 | 1 | 2 | 2 | 2 | 2 | 1 |
| | glass | | | | | | | | | | | |
| | phase | | | | | | | | | | | |

| | | Example 8 | | | | | | | | | | | |
|---|---|---|---|---|---|---|---|---|---|---|---|---|---|
| Position number | | 1 | 2 | 3 | 4 | 5 | 6 | 7 | 8 | 9 | 10 | 11 | 12 |
| Analysis | SiO₂ | 64.3 | 70.9 | 64.5 | 69.5 | 75.2 | 83.3 | 48.4 | 54.7 | 42.8 | 36.8 | 40.6 | 71.3 |
| values | MnO | 58.0 | 53.1 | 48.6 | 51.7 | 8.3 | 11.0 | 46.4 | 52.0 | 43.4 | 37.8 | 9.1 | 4.7 |
| | SiO₂/(SiO₂ + | 52.6 | 57.2 | 57.0 | 57.3 | 90.1 | 88.3 | 51.1 | 51.3 | 49.7 | 49.3 | 81.7 | 93.8 |
| | MnO) | | | | | | | | | | | | |
| | Type of | 2 | 2 | 2 | 2 | 1 | 1 | 2 | 2 | 2 | 2 | 1 | 1 |
| | glass | | | | | | | | | | | | |
| | phase | | | | | | | | | | | | |

As shown in FIG. 8, in Example 6, two kinds of glass phases were observed on the SEM image. Further, as shown in Table 5, in Example 6, the content ratio of SiO₂ to the sum of SiO₂ and MnO at eight positions (measurement positions 1 to 4 and 7 to 10) at which the glass phase appeared bright among eleven measurement positions for the glass phases ranged from 51.4% by mass to 56.6% by mass. The content ratio of SiO₂ to the sum of SiO₂ and MnO at three positions (measurement positions 5, 6, and 11) at which the glass phases appeared dark was 77.5% by mass to 91.6% by mass.

As shown in FIG. 9, in Example 8, two kinds of glass phases were observed on the SEM image. Further, as shown in Table 5, in Example 8, the content ratio of SiO₂ to the sum of SiO₂ and MnO at eight positions (measurement positions 1 to 4 and 7 to 10) at which the glass phase appeared bright among twelfth measurement positions for the glass phases ranged from 49.3% by mass to 57.3 by mass. The content ratio of SiO₂ to the sum of SiO₂ and MnO at four positions (measurement positions 5, 6, 11, and 12) at which the glass phases appeared dark was 81.7% by mass to 93.8% by mass.

In FIG. 11, the content ratio of SiO₂ to the sum of SiO₂ and MnO at the measurement positions in Comparative Examples 2 and 4 and Examples 2, 4, 6, and 8 is shown graphically. As shown in FIG. 11, in Comparative Examples 2 and 4, the content ratio of SiO₂ to the sum of SiO₂ and MnO lay between 40% by mass and 60% by mass for all of the measurement positions. Thus, only the second glass phase was formed. Meanwhile, in Examples 2, 4, 6, and 8, it was confirmed that the second glass phase in which the content ratio of SiO₂ to the sum of SiO₂ and MnO lay between 40% by mass and 60% by mass and the first glass phase in which the content ratio of SiO₂ to the sum of SiO₂ and MnO exceeded 75% by mass were formed in a clearly distinctive manner.

It is to be understood that the embodiments and Examples disclosed herein are merely examples in all aspects and in no way intended to limit the present disclosure in any aspect. The scope of the present disclosure is defined by the appended claims and not by the above description, and it is intended that the present disclosure encompasses all modifications made within the scope and spirit equivalent to those of the appended claims.

### REFERENCE SIGNS LIST

1 crystal unit, 101 package, 100 base portion, 110 board portion, 112 frame portion, 600 metallization layer, 10 sintered body, 11 alumina phase, 21 first glass phase, 31 second glass phase, 51 air gap

1. A sintered body containing Al₂O₃, SiO₂, and MnO, the sintered body comprising:
a main crystal phase formed of Al₂O₃;
a first glass phase; and
a second glass phase having a composition different from a composition of the first glass phase,
wherein the first glass phase is a phase containing SiO₂ and MnO,
wherein the second glass phase is a phase containing SiO₂ and MnO, and
wherein a content ratio of SiO₂ to a sum of SiO₂ and MnO in the first glass phase is larger than a content ratio of SiO₂ to a sum of SiO₂ and MnO in the second glass phase.

2. The sintered body according to claim 1,
wherein the first glass phase is a phase containing SiO₂ at the content ratio of 65% by mass or more and less than 100% by mass to the sum of SiO₂ and MnO, and
wherein the second glass phase is a phase containing SiO₂ at the content ratio of 35% by mass or more and less than 65% by mass to the sum of SiO₂ and MnO.

3. The sintered body according to claim 1, wherein, in the sintered body,
a content ratio of a sum of SiO₂ and MnO to entire mass of the sintered body is 11.0% by mass or more and 30.0% by mass or less, and
a content ratio of SiO₂ to the sum of SiO₂ and MnO is 54.0% by mass or more and 66.6% by mass or less in the sintered body.

4. The sintered body according to claim 1,
wherein an area ratio of the first glass phase, which is obtained from an image obtained by binarizing a scanning electron microscopic image of the sintered body, is 0.1% by area or more and 10% by area or less, and
wherein an area ratio of the second glass phase, which is obtained from the image obtained by binarizing the scanning electron microscopic image of the sintered body, is 10% by area or more and 30% by area or less.

5. The sintered body according to claim 1,
wherein the sintered body has a strength of 300 MPa or higher and 660 MPa or lower and a Young's modulus of 170 GPa or higher and 290 GPa or lower, and
wherein, on a graph having a vertical axis corresponding to a y-axis representing the strength in MPa and a horizontal axis corresponding to an x-axis representing the Young's modulus in GPa, coordinates of the strength and the Young's modulus of the sintered body lie between a straight line: y=1.7x+18 and a straight line: y=1.7x+168.

6. The sintered body according to claim 2, wherein, in the sintered body,
a content ratio of a sum of SiO₂ and MnO to entire mass of the sintered body is 11.0% by mass or more and 30.0% by mass or less, and
a content ratio of SiO₂ to the sum of SiO₂ and MnO is 54.0% by mass or more and 66.6% by mass or less in the sintered body.

7. The sintered body according to claim 2,
wherein an area ratio of the first glass phase, which is obtained from an image obtained by binarizing a scanning electron microscopic image of the sintered body, is 0.1% by area or more and 10% by area or less, and
wherein an area ratio of the second glass phase, which is obtained from the image obtained by binarizing the scanning electron microscopic image of the sintered body, is 10% by area or more and 30% by area or less.

8. The sintered body according to claim 2,
wherein the sintered body has a strength of 300 MPa or higher and 660 MPa or lower and a Young's modulus of 170 GPa or higher and 290 GPa or lower, and
wherein, on a graph having a vertical axis corresponding to a y-axis representing the strength in MPa and a horizontal axis corresponding to an x-axis representing the Young's modulus in GPa, coordinates of the strength and the Young's modulus of the sintered body lie between a straight line: y=1.7x+18 and a straight line: y=1.7x+168.
